(19) United States
(12) Patent Application Publication
(10) Pub. No.: US 2014/0071759 A1
(43) Pub. Date: Mar. 13, 2014

(54) NONVOLATILE MEMORY DEVICE

(71) Applicant: KABUSHIKI KAISHA TOSHIBA, Tokyo (JP)

(72) Inventors: Fumito NOMURA, Kanagawa-ken (JP); Hideto Takekida, Aichi-ken (JP); Wataru Sakamoto, Mie-ken (JP)

(73) Assignee: Kabushiki Kaisha Toshiba, Tokyo (JP)

(21) Appl. No.: 13/774,220

(22) Filed: Feb. 22, 2013

(30) Foreign Application Priority Data
Sep. 11, 2012 (JP) 2012-199938

(51) Int. Cl. G11C 16/04

(52) U.S. Cl. CPC G11C 16/04
USPC 365/185.17

(57) ABSTRACT

According to an embodiment, a nonvolatile memory device includes a plurality of memory cell strings disposed in parallel in a first direction, a bit line and a first contact plug. Each of the memory cell strings extends in a second direction orthogonal to the first direction and includes a plurality of memory cells disposed in parallel in the second direction. The bit line is shared by two adjacent memory cell strings of the memory cell strings, and the first contact plug is connected to the bit line and one of the two adjacent memory cell strings. The bit line includes a first transistor section controlling a current flowing in the one of the adjacent memory cell strings.

### CROSS-REFERENCE TO RELATED APPLICATIONS

This application is based upon and claims the benefit of priority from Japanese Patent Application No. 2012-199938, filed on Sep. 11, 2012; the entire contents of which are incorporated herein by reference.

### FIELD

Embodiments are generally related to a nonvolatile memory device.

### BACKGROUND

The nonvolatile memory device such as NAND flash memory includes miniaturized memory cells. Accordingly, the pitch of bit lines is narrowed, and the line width is reduced. Thus, the resistance and parasitic capacitance of the bit line may degrade the performance of the device.

The bit line of a NAND flash memory is used to pass a current in the memory cell string. The bit line is typically longer than the word line. Thus, in the bit line with a reduced line width, its resistance and parasitic capacitance result in longer time for charging and discharging. Accordingly, the time required for writing and reading the memory cell is also made longer. In this context, there is a method for associating one bit line with two memory cell strings instead of establishing one-to-one correspondence between the bit line and the memory cell string. This can double the line pitch of bit lines to suppress the performance degradation. However, in the case where one bit line is shared by two memory cell strings, means for selecting each memory cell string is needed.

### BRIEF DESCRIPTION OF THE DRAWINGS

FIGS. 1A and 1B are schematic views illustrating one example of a nonvolatile memory device according to a first embodiment;

FIGS. 2A and 2B are schematic views illustrating one example of the memory cell section of the nonvolatile memory device according to the first embodiment;

FIGS. 3A to 3D are schematic views illustrating one example of wiring layers of the nonvolatile memory device according to the first embodiment;

FIGS. 4A to 6B are schematic sectional views illustrating one example of a manufacturing process of the nonvolatile memory device according to the first embodiment;

FIGS. 7A and 7B are schematic sectional views illustrating one example of a manufacturing process of a nonvolatile memory device according to a variation of the first embodiment;

FIGS. 8A to 8C are schematic sectional views illustrating one example of the nonvolatile memory device according to the variation of the first embodiment;

FIGS. 9A and 9B are schematic views illustrating one example of a nonvolatile memory device according to a second embodiment;

FIGS. 10A to 12B are schematic sectional views illustrating one example of a manufacturing process of the nonvolatile memory device according to the second embodiment; and

FIGS. 13A to 15 are schematic sectional views illustrating one example of a manufacturing process of a nonvolatile memory device according to a variation of the second embodiment.

### DETAILED DESCRIPTION

According to an embodiment, a nonvolatile memory device includes a plurality of memory cell strings disposed in parallel in a first direction, a bit line and a first contact plug. Each of the memory cell strings extends in a second direction orthogonal to the first direction and includes a plurality of memory cells disposed in parallel in the second direction. The bit line is shared by two adjacent memory cell strings of the memory cell strings, and the first contact plug is connected to the bit line and one of the two adjacent memory cell strings. The bit line includes a first transistor section controlling a current flowing in the one of the adjacent memory cell strings.

Embodiments will now be described with reference to the drawings. Like portions in the drawings are labeled with like reference numerals, with the detailed description thereof omitted appropriately, and the different portions are described. Various components may be described with reference to the XYZ orthogonal coordinate system shown in the drawings.

### First Embodiment

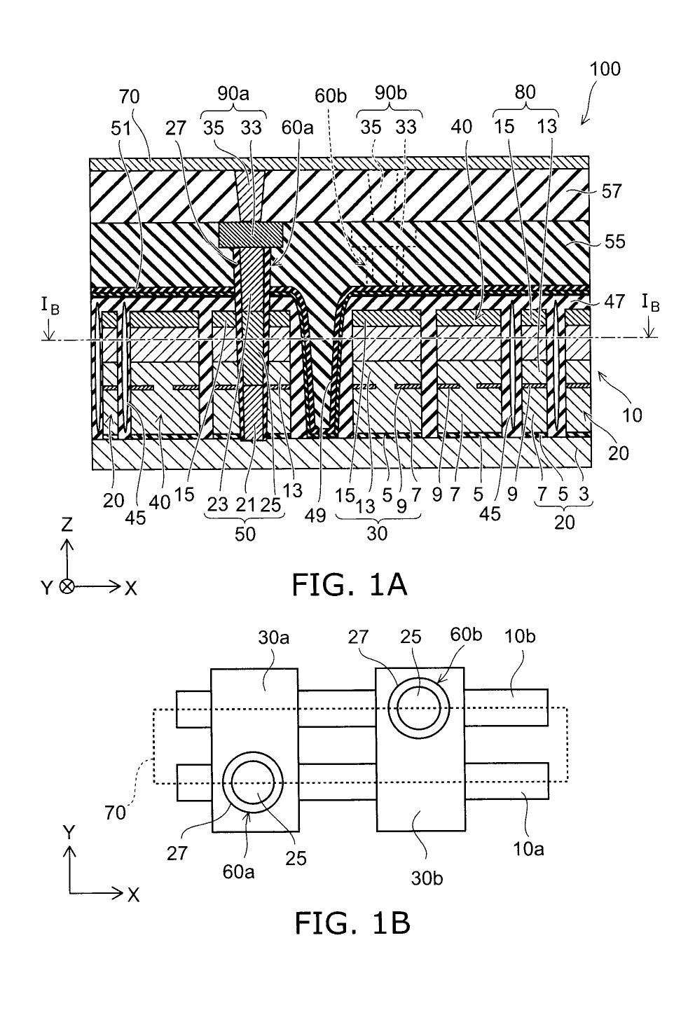

FIGS. 1A and 1B are schematic views showing one example of a nonvolatile memory device 100 according to a first embodiment. The nonvolatile memory device 100 is e.g. a NAND flash memory, and includes a plurality of NAND strings (memory cell strings).

FIG. 1A shows a cross section of the connecting portion between a memory cell string 10 and a bit line 70 provided on the memory cell string 10 via interlayer insulating films 55 and 57. FIG. 1B is a schematic view showing I_{B}-I_{B} cross section in FIG. 1A.

As shown in FIG. 1A, the memory cell string 10 includes a plurality of memory cells 20 provided on a semiconductor layer 3, a first select gate (hereinafter, select gate 30), and a second select gate (hereinafter, select gate 40). The memory cell 20 and each select gate include a tunnel insulating film 5, a polycrystalline silicon layer (hereinafter, polysilicon layer) 7, an IPD (inter-poly dielectric) film 9, and a polysilicon layer 13, collectively formed on the semiconductor layer 3. The upper portion of the polysilicon layer 13 may include a silicide layer. The silicide layer is formed by silicidizing the upper portion of the polysilicon layer 13. A silicon nitride layer 15 is provided on the polysilicon layer 13.

The memory cell 20 includes part of the semiconductor layer 3, the tunnel insulating film 5, and the polysilicon layer 7 serving as a charge accumulation layer. Furthermore, on the polysilicon layer 7, a control gate 80 is provided via the IPD film 9. The control gate 80 includes the polysilicon layer 13 and the silicon nitride layer 15.

In the select gate 40, an opening is provided in the IPD film 9. Thus, the polysilicon layer 7 and the polysilicon layer 13 are electrically connected.

The select gate 30, the select gate 40, and the memory cell 20 insulated from each other by an insulating layer 47 are disposed in parallel on the semiconductor layer 3. A gap 45 for reducing parasitic capacitance may be provided between the select gate 40 and the memory cell 20 and between the adjacent memory cells 20. On the memory cells 20 and the select gates 30, 40, the interlayer insulating films 55 and 57 are provided via an insulating film 51.

In this embodiment is provided a contact plug 60 for electrically connecting the memory cell string 10 to the bit line 70 provided on the interlayer insulating film 57. The contact plug 60 includes a transistor section 50 placed on the memory cell string 10 side, and a wiring section 90 placed on the bit line 70 side.

In the following description, in the case of generally mentioning a contact plug, it is denoted as “contact plug 60”. On the other hand, in the case of mentioning a particular contact plug, it is denoted as “contact plug 60a” (first contact plug) and “contact plug 60b” (second contact plug). The same applies to other components. In the following description, the first conductivity type is n-type, and the second conductivity type is p-type. However, the embodiments are not limited thereto, but n-type and p-type may be interchanged. That is, the first conductivity type may be p-type, and the second conductivity type may be n-type.

The transistor section 50 penetrates through the select gate 30. The transistor section 50 includes an n-type source region 21 (first region) in contact with the p-type semiconductor layer 3, an n-type drain region 23 (second region) in contact with the wiring section 90, and a p-type channel region 25 (third region). The p-type channel region 25 is opposed to the polysilicon layer 13 of the select gate 30 across a gate insulating film 27. That is, the polysilicon layer 13 serves as a gate electrode for turning on and off the transistor section 50.

The transistor section 50 is an n-channel MOS transistor. By applying a positive voltage higher than or equal to a threshold voltage of the transistor section 50 to the polysilicon layer 13, the transistor section 50 is turned on. In this case, the channel current flows in the direction from the bit line 70 to the semiconductor layer 3 (−Z direction) through an accumulation channel formed at the interface between the gate insulating film 27 and the p-type channel region 25.

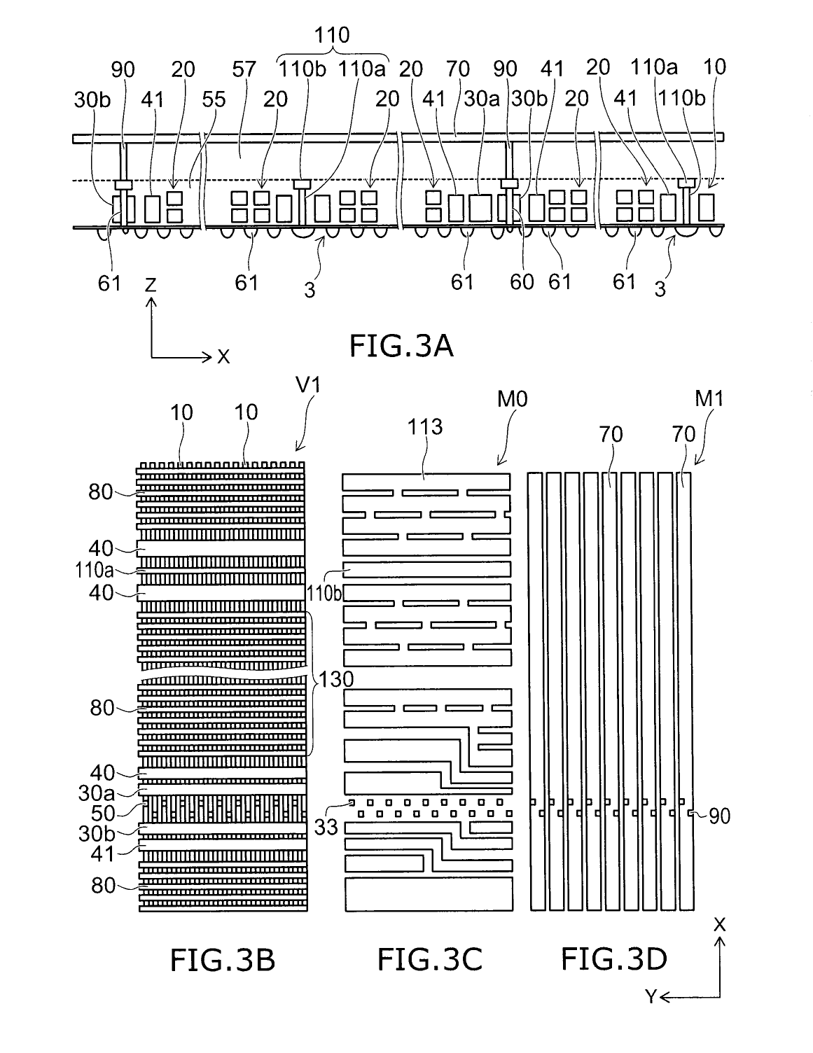

By applying a positive voltage to the polysilicon layer 13, an accumulation channel is formed also at the interface between the tunnel insulating film 5 and the semiconductor layer 3 of the select gate 30. Thus, a current can be passed from the source region 21 in contact with the semiconductor layer 3 through the select transistor 41 to the source/drain region 61 (see FIG. 3A) of the memory cell 20.

The wiring section 90 includes a wiring 33 provided on the interlayer insulating film 55, and a plug 35 provided in the interlayer insulating film 57. The wiring 33 and the plug 35 are made of e.g. a metal including tungsten (W), and electrically connect the n-type drain region 23 to the bit line 70.

As shown in FIG. 1B, the bit line 70 is shared by two memory cell strings 10a and 10b. The contact plug 60a connects between the bit line 70 and the memory cell string 10a. The contact plug 60b connects between the bit line 70 and the memory cell string 10b.

The memory cell strings 10a and 10b are disposed in parallel in a first direction (Y direction), and extend in a second direction (X direction) orthogonal to the first direction. The select gate 30a extends in the Y direction and serves as a gate electrode for turning on and off a transistor section 50 (first transistor section). On the other hand, the select gate 30b also extends in the Y direction and serves as a gate electrode for turning on and off a transistor section 50 (second transistor section).

As shown in FIG. 1B, the channel region 25 of the transistor section 50 is surrounded with the gate insulating film 27, which is further surrounded with the select gate 30. Thus, the transistor section 50 is a MOS transistor having what is called the surround gate structure.

As described above, the transistor sections 50 included in the contact plugs 60a and 60b connected to one bit line 70 are controlled by different select gates 30. Thus, the connection between the bit line 70 and the memory cell string 10a or 10b can be selected.

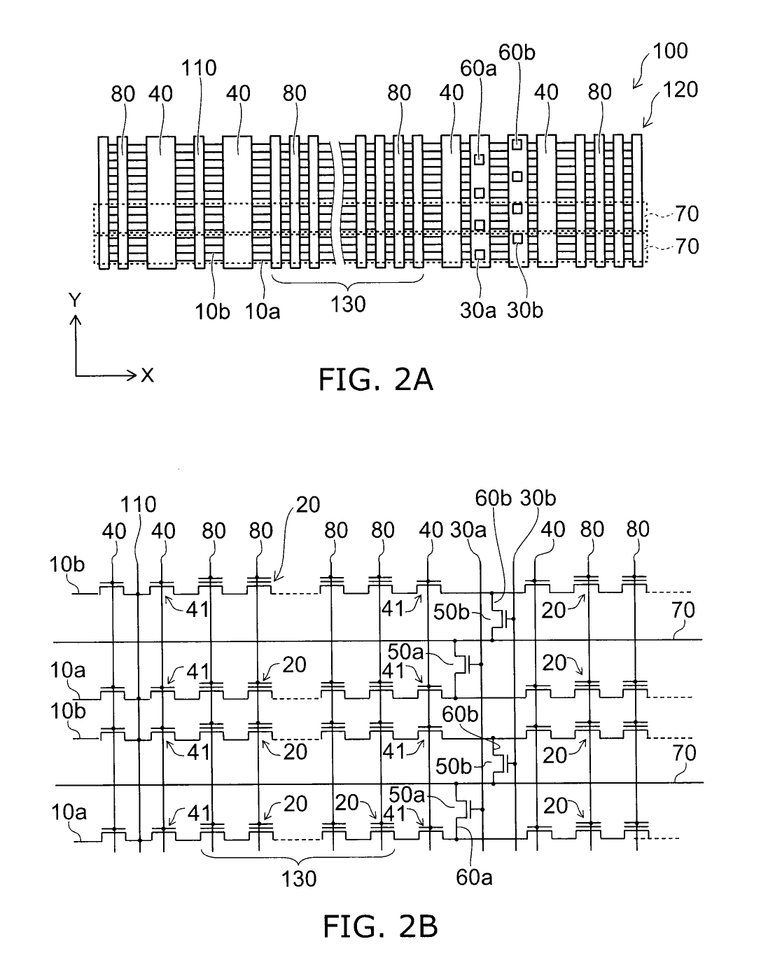

FIGS. 2A and 2B are schematic views showing one example of the memory cell section 120 of the nonvolatile memory device 100 according to the first embodiment. FIG. 2A is a plan view showing the layout of the memory cell section 120. FIG. 2B shows an equivalent circuit thereof.

The memory cell section 120 includes a plurality of memory cell strings 10 disposed in parallel in the Y direction. Each memory cell string 10 extends in the X direction. The memory cell section 120 further includes a plurality of control gates 80 extending in the Y direction. A memory cell 20 is provided at the intersection of the memory cell string 10 and the control gate 80. Thus, the memory cell string 10 includes a plurality of memory cells 20 disposed in parallel in the X direction.

The memory cell section 120 includes a memory cell block 130 in which a plurality of memory cells 20 are arranged in a matrix. That is, the memory cell block 130 includes a plurality of memory cell strings 10 each including a plurality of memory cells 20 disposed in parallel therein. A plurality of memory cells sharing a control gate 80 extending in the Y direction are provided respectively in different memory cell strings 10.

The select gates 40 are provided on both sides of the memory cell block 130 in the X direction. The select gate 40 extends in the Y direction. A select transistor 41 is provided at the intersection of the select gate 40 and the memory cell string 10. The select transistor 41 performs on/off control of the current flowing in each memory cell string 10 by the voltage applied to the select gate 40. Thus, two select gates provided on both sides of the memory cell block 130 control the current flowing in a plurality of memory cell strings 10 belonging to that memory cell block 130.

Furthermore, a source line 110 and a select gate 30 are provided on both sides in the X direction of the memory cell block 130 and the two select gates 40. That is, the memory cell block 130 and the two select gates 40 are disposed between the source line 110 and the select gate 30. The select gate 30 extends in the Y direction and is disposed in parallel with the select gate 40. The source line 110 also extends in the Y direction and is disposed in parallel with the select gate 40.

As shown in FIG. 2B, a plurality of memory cell strings 10a, 10b share a source line 110. The adjacent memory cell strings 10a and 10b share one bit line 70.

The bit line 70 and the memory cell string 10a are connected via the transistor section 50a. The bit line 70 and the memory cell string 10b are connected via the transistor section 50b. The gate of the transistor section 50a is controlled by the select gate 30a. The gate of the transistor section 50b is controlled by the select gate 30b.

FIGS. 3A to 3D are schematic views showing one example of the wiring layer of the nonvolatile memory device 100. FIG. 3A is a sectional view along the X direction of the memory cell string 10. FIG. 3B shows a layout V1 on the upper face of the semiconductor layer 3. FIG. 3C shows a wiring pattern on the interlayer insulating film 55. FIG. 3D shows a pattern of the bit lines provided on the interlayer insulating film 57.

As shown in FIG. 3A, in the semiconductor layer 3, n-type source/drain regions 61 are provided between the adjacent memory cells 20, between the memory cell 20 and the select gate 40, and between the adjacent select gates. The source line 110 includes a contact portion 110a in contact with the semiconductor layer 3, and a source wiring 110b provided on the interlayer insulating film 55.

As shown in FIG. 3B, a plurality of memory cell strings 10 are disposed in parallel in the Y direction. A plurality of control gates 80 extend in the Y direction and each cross the plurality of memory cell strings 10. On both sides of one memory cell block 130, the select gates 40 extend in the Y direction. The contact portion 110a of the source line 110 is disposed on the source side of the memory cell block 130. The select gates 30a, 30b are placed on the drain side of the memory cell block 130.

The source line 110 is applied with 0 V at the time of reading operation. Thus, it may be a collective wiring in contact with a plurality of memory cell strings 10. On the other hand, a contact plug 60 is provided on the drain side and in contact with each memory cell string. The contact plug 60 includes a transistor section 50 in the layout V1 at the same level as the memory cell 20 and the select gate 40.

FIG. 3C shows a first-layer interlayer wiring M0 provided on the interlayer insulating film 55 covering the memory cells 20 and the select gates. The interlayer wiring M0 includes a source wiring 110b, a control gate wiring 113, and a wiring 33 of the contact plug 60.

FIG. 3D shows a second-layer interlayer wiring M1 provided on the interlayer insulating film 57. The interlayer wiring M1 includes a plurality of bit lines 70 extending in the X direction. A wiring section 90 of the contact plug 60 is connected to the bit line 70. The bit line 70 is shared by two memory cell strings 10a, 10b via the contact plugs 60a, 60b, respectively. Thus, the bit lines 70 can be provided at a double line pitch of the memory cell strings 10. This can reduce the resistance and parasitic capacitance thereof.

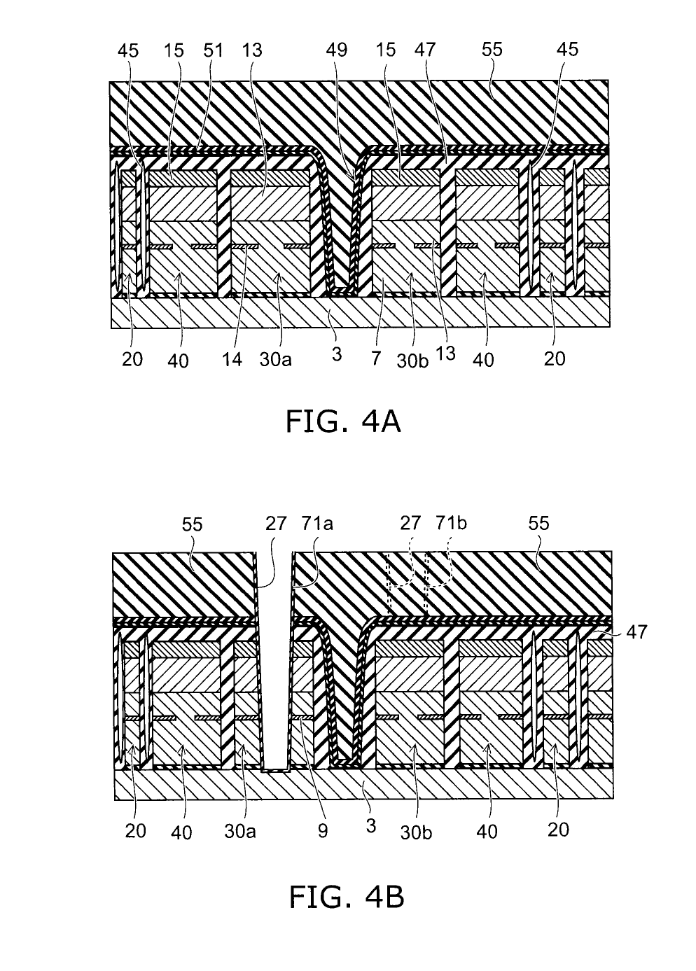

Next, one example of a manufacturing process of the nonvolatile memory device 100 according to the first embodiment is described with reference to FIGS. 4A to 6B. FIGS. 4A and 4B show part of the cross section along the X direction of the memory cell string 10.

As shown in FIG. 4A, on a semiconductor layer 3, memory cells 20, a select gate 30, and a select gate 40 are provided and covered with an insulating layer 47. Here, a gap 45 is provided between the adjacent memory cells 20 and between the memory cell 20 and the select gate 40.

In forming the memory cells 20 and the select gates, a tunnel insulating film 5, a polysilicon layer 7, an IPD film 9, and a polysilicon layer 13 are sequentially stacked on the semiconductor layer 3, and etched in respective prescribed patterns. In the embodiment, the select gate 30 is provided without an additional process. Subsequently, the insulating layer 47 is patterned to provide a depression 49 reaching the semiconductor layer 3. Then, an insulating film 51 and an interlayer insulating film 55 are formed on the insulating layer 47.

As shown in FIG. 4B, a contact hole 71 extending from the upper face of the interlayer insulating film 55 to the semiconductor layer 3 is formed. The contact hole 71 may be formed using e.g. RIE (reactive ion etching) technique. Subsequently, a gate insulating film 27 is formed on the inner surface of the contact hole 71. The gate insulating film 27 is formed using e.g. CVD (chemical vapor deposition) technique. Furthermore, the gate insulating film 27 formed on the bottom surface of the contact hole 71 is selectively removed using e.g. anisotropic RIE technique.

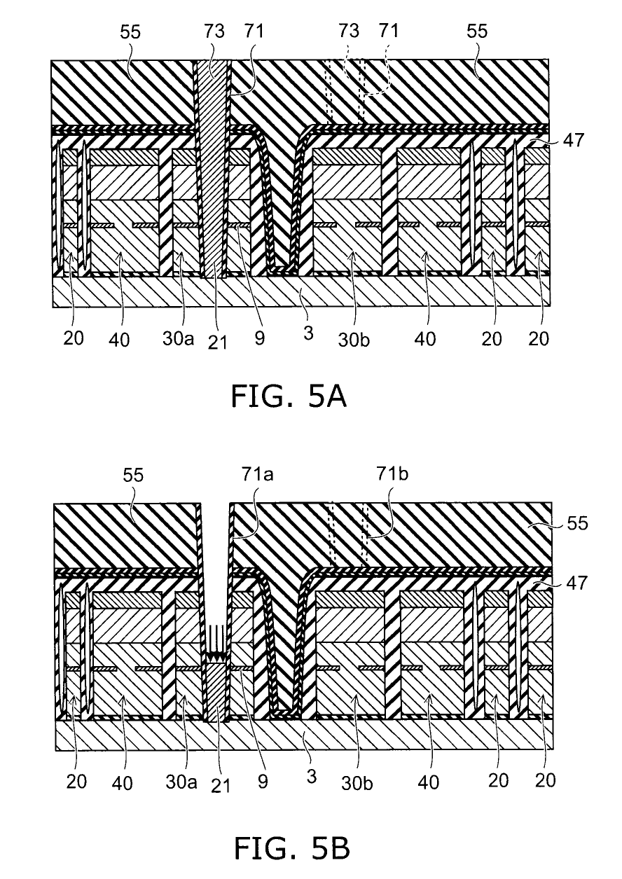

As shown in FIG. 5A, polysilicon 73 is formed inside the contact hole 71. For instance, by using CVD technique, a polysilicon layer is formed inside the contact hole 71 and on the interlayer insulating film 55. Then, the portion deposited on the interlayer insulating film 55 is removed using CMP (chemical mechanical polishing) technique. Thus, the polysilicon 73 can be formed.

As shown in FIG. 5B, the polysilicon 73 is etched back and dug down to the same depth as the IPD film 9. Subsequently, n-type impurity such as arsenic (As) or phosphorus (P) is ion implanted into the polysilicon 73 remaining in the lower portion of the contact hole 71, in order to form an n-type source region 21.

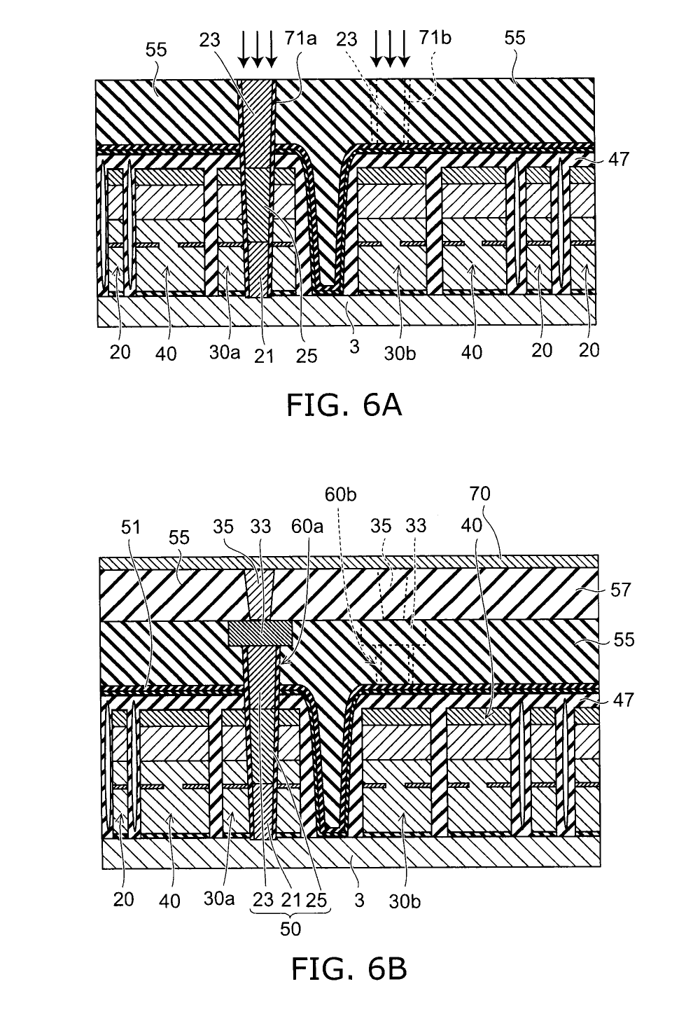

As shown in FIG. 6A, p-type polysilicon constituting a p-type channel region 25 is embedded in the space of the contact hole 71 above the n-type source region 21. Subsequently, n-type impurity is ion implanted into the upper portion of that p-type polysilicon to form an n-type drain region 23. The n-type drain region 23 is formed so that its lower end is located near the upper face of the select gate 30.

As shown in FIG. 6B, an interlayer wiring M0 is formed on the interlayer insulating film 55. The interlayer wiring M0 is e.g. a metal wiring including tungsten (W). The interlayer wiring M0 includes a wiring 33 in contact with the drain region 23. Furthermore, a second-layer interlayer insulating film 57 is formed, and a plug 35 connected to the wiring 33 is formed. Subsequently, bit lines 70 are formed on the interlayer insulating film 57. The cross-sectional area of the wiring 33 in the XY plane is larger than the cross-sectional area of the drain region 23. This facilitates electrical connection between the plug 35 and the transistor section 50.

Thus, in the embodiment, a vertical transistor is formed inside the contact hole 71 penetrating through the select gate 30. Accordingly, a transistor section 50 for selecting one of the adjacent memory cell strings 10a and 10b to make it continuous with the bit line 70 can be formed with minimum space. That is, the space efficiency of the memory cell section 120 can be improved to reduce the manufacturing cost.

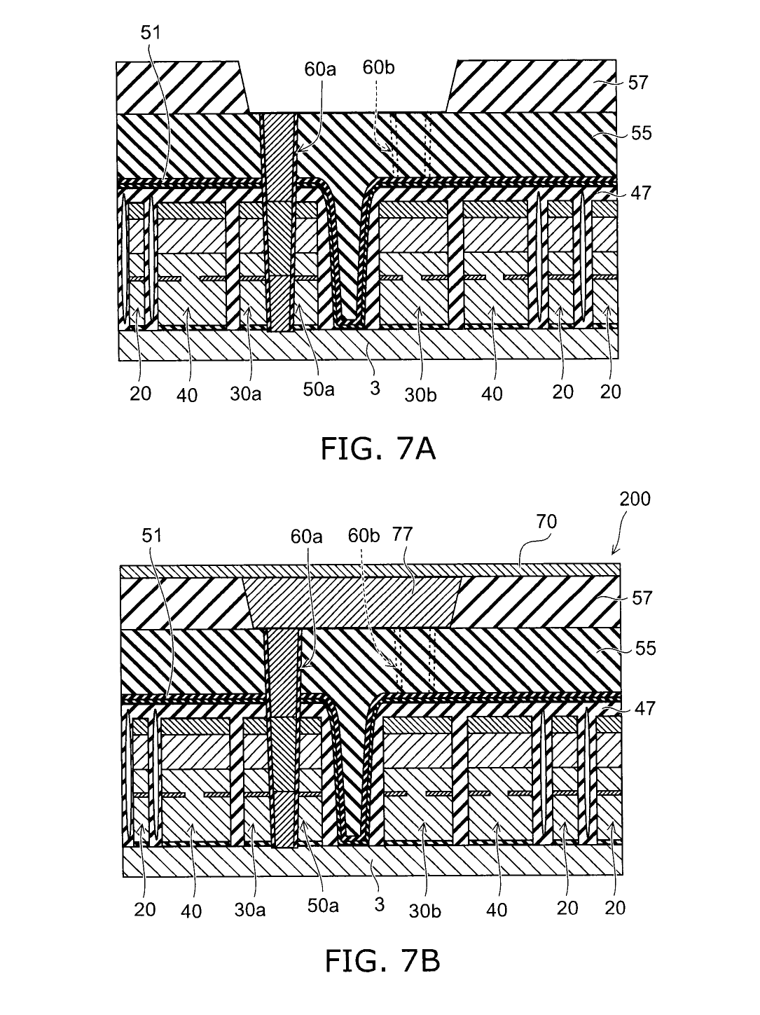

FIGS. 7A and 7B are schematic sectional views showing a process for manufacturing a nonvolatile memory device 200 according to a variation of the first embodiment.

As shown in FIG. 7A, after forming the interlayer insulating film 57, a recess 75 reaching the interlayer insulating film 55 is formed. Thus, the drain region 23 of the transistor sections 50a and 50b is exposed at the bottom surface of the recess 75.

As shown in FIG. 7B, a metal wiring 77 is formed inside the recess 75, and bit lines 70 are formed thereon. The metal wiring 77 is a wiring section for connecting the transistor sections 50a and 50b to the bit line 70.

In forming the metal wiring 77, a metal layer including tungsten (W) is formed, for instance, using CVD technique inside the recess 75 and on the interlayer insulating film 57. Then, the metal layer on the interlayer insulating film 57 is removed using CMP technique. Thus, the metal wiring 77 can be formed.

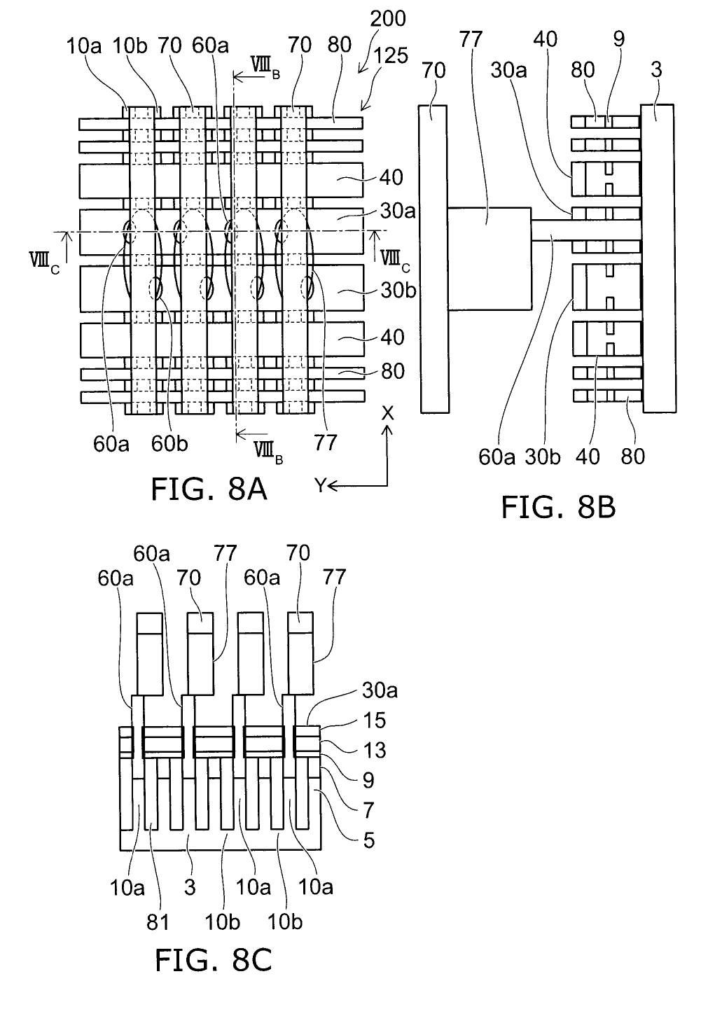

FIGS. 8A to 8C are schematic sectional views showing one example of the nonvolatile memory device 200 according to the variation of the first embodiment. FIG. 8A is a plan view showing the layout of the memory cell section 125. FIGS. 8B and 8C show cross-sectional structures along VIII_{B}-VIII_{B} and VIII_{A}-VIII_{A} lines shown in FIG. 8A, respectively.

As shown in FIGS. 8A and 8B, the metal wiring 77 is provided astride the select gates 30a and 30b. The metal wiring 77 is connected to both the contact plug 60a penetrating through the select gate 30a and the contact plug 60b penetrating through the select gate 30b.

As shown in FIG. 8C, the memory cell strings 10a and 10b are insulated from each other by an STI (shallow trench isolation) 81. The select gate 30a includes e.g. a polysilicon layer 7 formed on each memory cell string 10 via the tunnel insulating film 5, an IPD film 9 extending astride a plurality of memory cell strings 10, a polysilicon layer 13, and a silicon nitride layer 15.

In this variation, the metal wiring 77 is provided astride the select gates 30a and 30b in the X direction, and astride the adjacent memory cell strings 10a and 10b in the Y direction. Thus, the area of the metal wiring 77 is expanded. This can enlarge the tolerance of alignment when contacting the bit line 70 to the contact plugs 60a and 60b.

### Second Embodiment

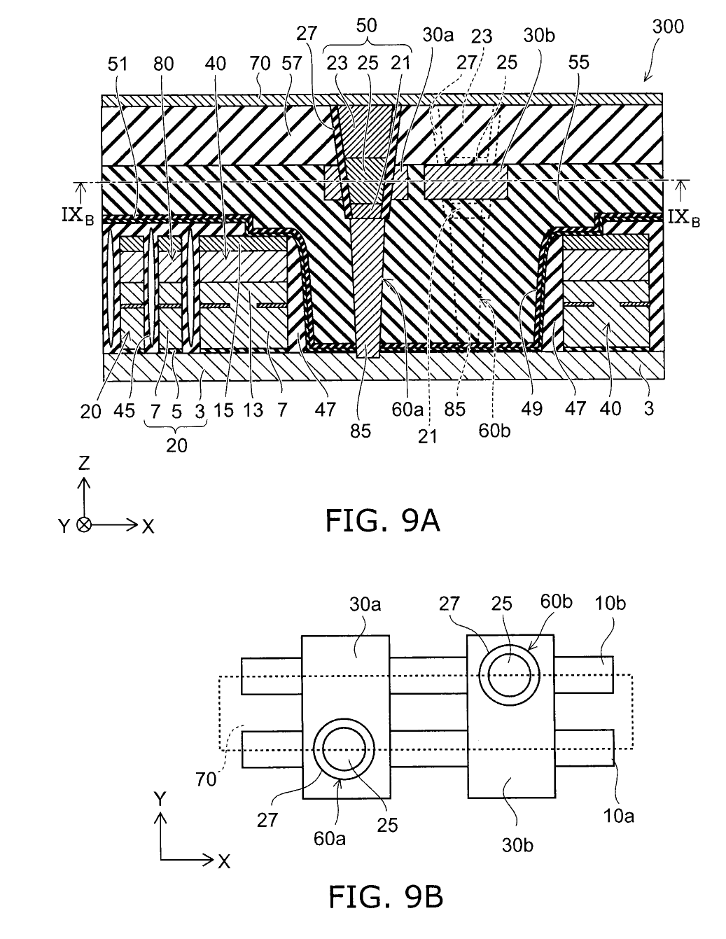

FIGS. 9A and 9B are schematic views showing one example of a nonvolatile memory device 300 according to a second embodiment.

FIG. 9A shows a cross section of the connecting portion between a memory cell string 10 and a bit line 70 provided on the memory cell string 10 via interlayer insulating films 55 and 57. FIG. 9B is a schematic cross-sectional view along IX_{B}-IX_{B} line shown in FIG. 9A.

As shown in FIG. 9A, the memory cell string 10 includes a plurality of memory cells 20 provided on a semiconductor layer 3, and select gates 40. Contact plugs 60a and 60b are provided between two select gates 40. The contact plugs 60a and 60b each include a transistor section 50 and a wiring section 85.

In the embodiment, the transistor section 50 is a vertical MOS transistor penetrating through the second-layer interlayer insulating film 57 to the depth reaching the first-layer interlayer insulating film 55. The select gates 30a and 30b for controlling the gate of the transistor section 50 are interlayer wirings provided in the upper face of the interlayer insulating film 55. The wiring section 85 connects the memory cell string 10 to the source region 21 of the transistor section 50. The bit line 70 is in contact with the drain region 23.

As shown in FIG. 9B, the channel region 25 of the transistor section 50 is surrounded with the gate insulating film 27, which is further surrounded with the select gate 30. The transistor sections 50 included in the contact plugs 60a and 60b connected to one bit line 70 are controlled by different select gates 30a and 30b, respectively. Thus, the connection between the bit line 70 and the memory cell string 10a or 10b can be selected by the transistor sections 50.

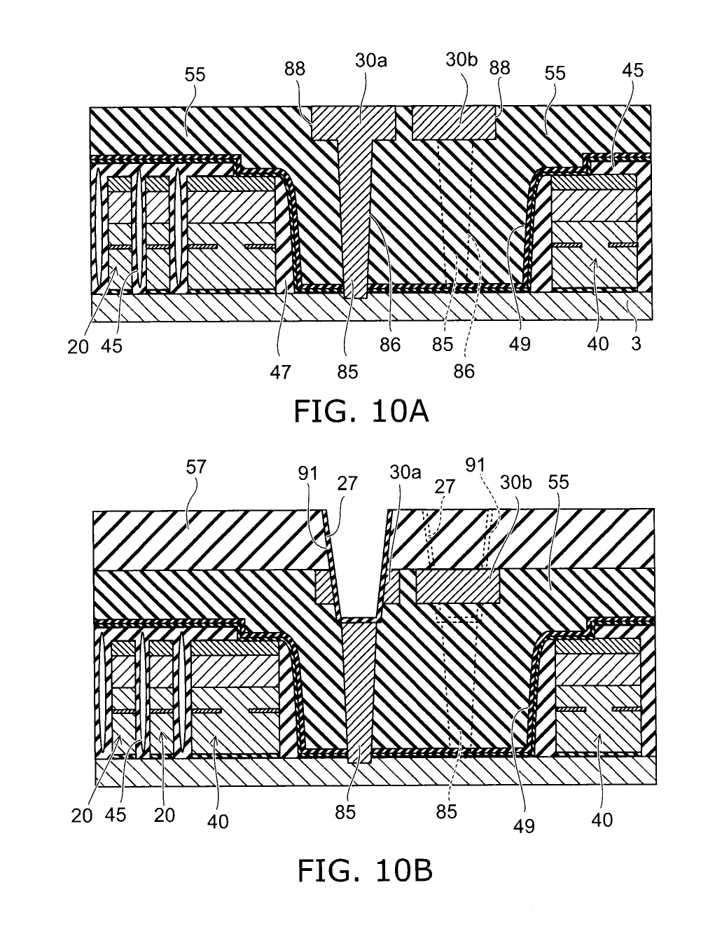

FIGS. 10A to 12B are schematic sectional views showing one example of a process for manufacturing the nonvolatile memory device 300 according to the second embodiment.

As shown in FIG. 10A, in the embodiment, an insulating layer 47 covering the memory cells 20 and select gates 40 is patterned to provide a depression 49 between two select gates 40. The depression 49 reaches the semiconductor layer 3. Then, an insulating film 51 and an interlayer insulating film 55 are formed on the insulating layer 47. Subsequently, a wiring section 85 extending from the upper face of the interlayer insulating film 55 to the semiconductor layer 3 is formed. The wiring section 85 is a plug embedded inside a contact hole 86.

The contact hole 86 is formed in the interlayer insulating film 55 by using e.g. RIE technique. In this contact processing, the contact hole 86 with a small diameter may be formed using the spacer processing. That is, a hole is first formed with a large hole diameter, and then partly filled back with a spacer of thin oxide film in the spacer processing.

Subsequently, in accordance with the contact hole 86, for instance, recesses 88 for embedding select gates 30a and 30b are formed. Then, a metal layer embedded in the contact hole 86 and the recess 88 is formed. The metal layer is made of e.g. a metal including tungsten (W), which can be formed by using CVD technique. Furthermore, by using CMP, the metal layer deposited on the interlayer insulating film 55 is removed. Thus, the wiring section 85 and the select gates 30a and 30b are completed.

The select gates 30a and 30b are included in e.g. the interlayer wiring M0, and extend in the same direction (Y direction) as the source line 110.

As shown in FIG. 10B, a second-layer interlayer insulating film 57 is formed on the interlayer insulating film 55, and a contact hole 91 is opened therein. The contact hole 91 is formed through the select gate 30 so that the upper face of the wiring section 85 is exposed at the bottom surface of the contact hole 91. For instance, the contact hole 91 is dug down to a depth of approximately 10 nm from the lower face of the select gate 30.

Subsequently, a gate insulating film 27 is formed on the inner surface of the contact hole 91. Then, the gate insulating film 27 formed on the bottom surface of the contact hole 91 is selectively removed by using e.g. anisotropic RIE technique.

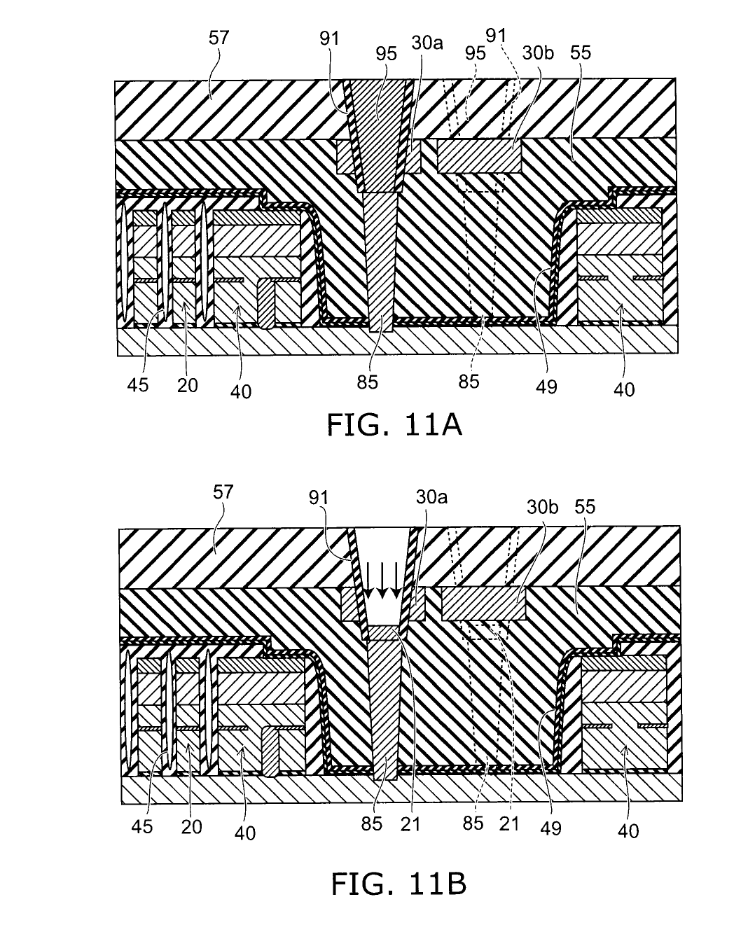

As shown in FIG. 11A, polysilicon 95 is formed inside the contact hole 91. For instance, a polysilicon layer is formed inside the contact hole 91 and on the interlayer insulating film 57. Then, the portion deposited on the interlayer insulating film 57 is removed using CMP technique. Thus, the polysilicon 95 can be formed so as to being in contact with the wiring section 85.

As shown in FIG. 11B, the polysilicon 95 is etched back and dug down to the same depth as the lower face of the select gate 30. Subsequently, n-type impurity such as arsenic (As) or phosphorus (P) is ion implanted into the polysilicon 95 to form an n-type source region 21.

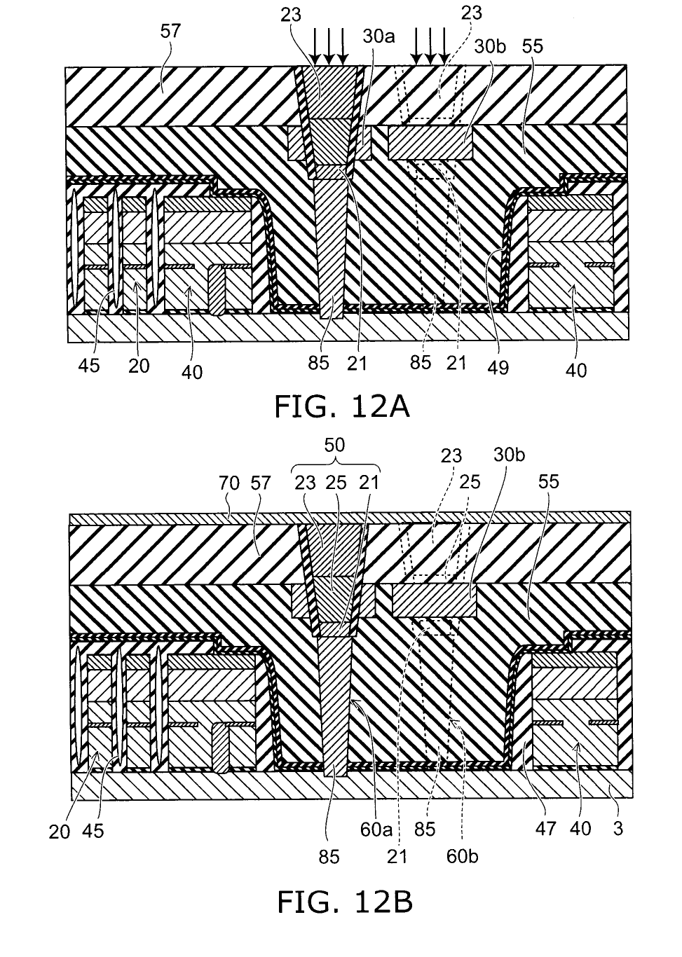

As shown in FIG. 12A, p-type polysilicon constituting a p-type channel region 25 is embedded in the space of the contact hole 91 above the n-type source region 21. Furthermore, n-type impurity is ion implanted into the upper portion of that p-type polysilicon to form an n-type drain region 23. The n-type drain region 23 is formed so that its lower end is located near the upper face of the select gate 30.

As shown in FIG. 12B, bit lines 70 are formed on the interlayer insulating film 57. As shown in this figure, the bit line 70 may be in direct contact with the drain region 23 of the transistor section 50. Alternatively, a contact layer may be provided between the bit line 70 and the drain region 23.

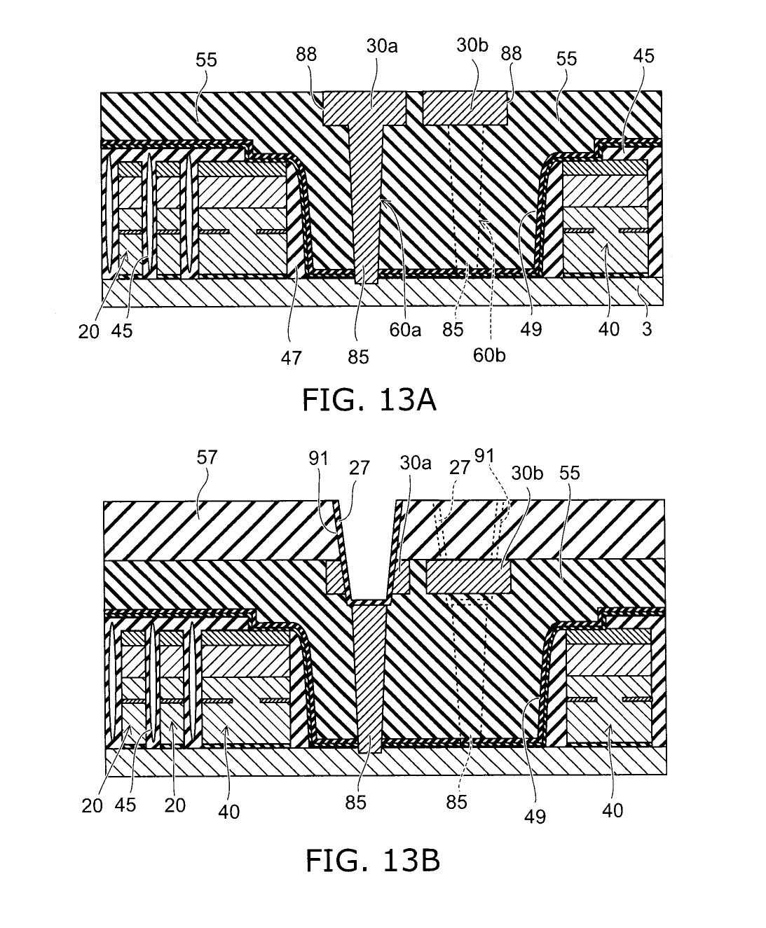

FIGS. 13A to 15 are schematic sectional views showing a process for manufacturing a nonvolatile memory device according to a variation of the second embodiment.

FIGS. 13A and 13B show the same process as FIGS. 10A and 10B, and the execution sequence is also the same. This variation is different from the process shown in FIGS. 10A and 10B in that the position of the bottom surface of the contact hole 91 is provided near the lower face of the select gate 30.

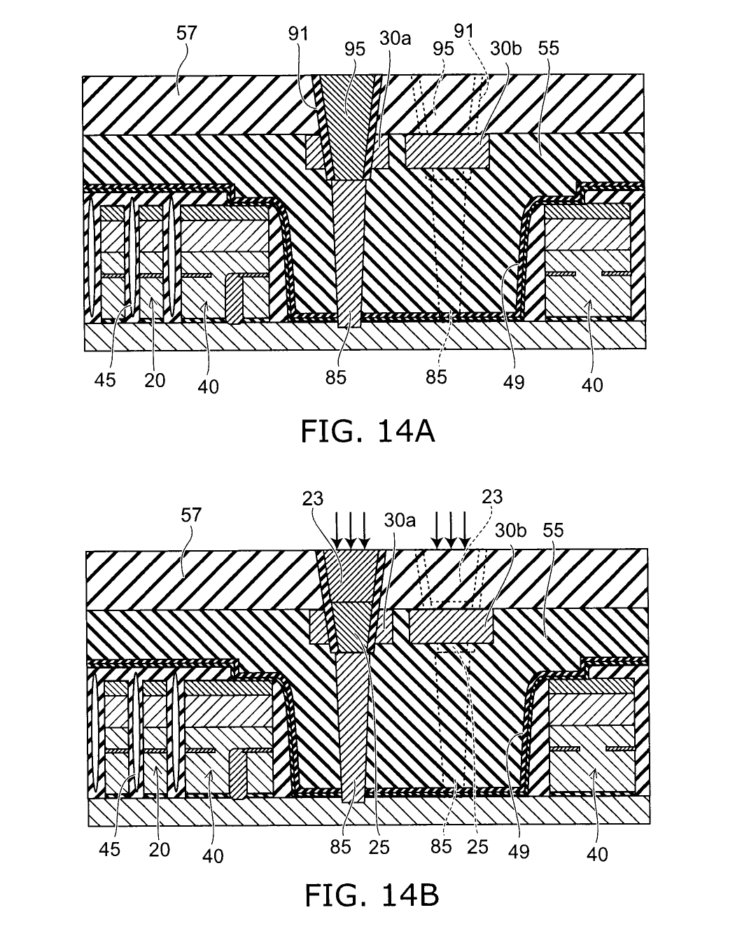

As shown in FIG. 14A, p-type polysilicon constituting a p-type channel region 25 is embedded inside the contact hole 91. Then, n-type impurity is ion implanted into the upper portion of that p-type polysilicon to form an n-type drain region 23. The n-type drain region 23 is formed so that its lower end is located near the upper face of the select gate 30.

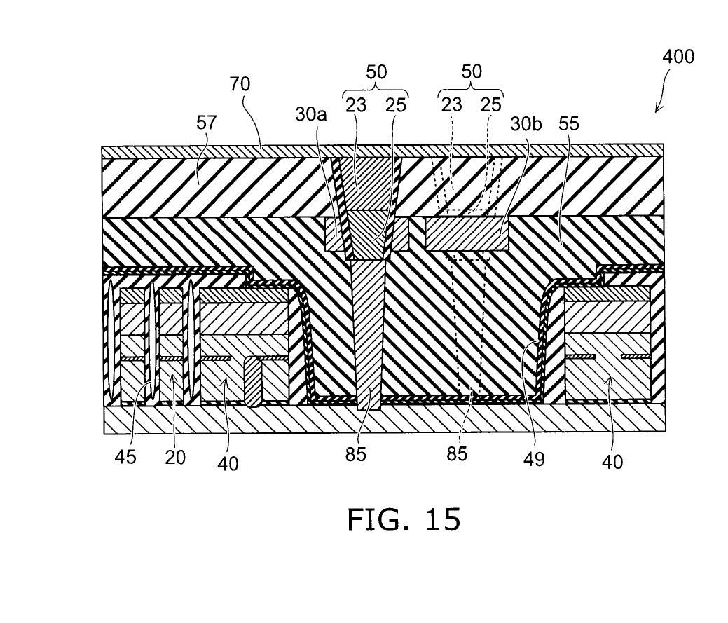

As shown in FIG. 15, bit lines 70 are formed on the interlayer insulating film 57. The bit line 70 may be in direct contact with the drain region 23 of the transistor section 50. Alternatively, a contact layer may be provided between the bit line 70 and the drain region 23.

In this variation, the step of depositing a polysilicon layer for forming an n-type source region 21 and etching it back can be omitted. The lower face of the select gate 30 is made close to the upper face of the wiring section 85. Thus, the lower portion of the channel region 25 can be inverted by the fringe electric field of the gate electrode. This enables on/off control of the transistor section 50.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile memory device comprising:
a plurality of memory cell strings disposed in parallel in a first direction, each of the memory cell strings extending in a second direction orthogonal to the first direction and including a plurality of memory cells disposed in parallel in the second direction;
a bit line shared by two adjacent memory cell strings of the memory cell strings; and
a first contact plug connected to the bit line and one of the two adjacent memory cell strings and including a first transistor section controlling a current flowing in the one of the adjacent memory cell strings.

2. The device according to claim 1, wherein the first transistor section includes a channel passing the current in a third direction orthogonal to the first direction and the second direction.

3. The device according to claim 1, wherein the first transistor section includes a first region of a first conductivity type electrically connected to the memory cell string, a second region of the first conductivity type electrically connected to the bit line, and a third region of a second conductivity type provided between the first region and the second region.

4. The device according to claim 3, wherein
the first region and the second region are made of n-type polysilicon, and
the third region is made of p-type polysilicon.

5. The device according to claim 3, further comprising:
a first select gate extending in the first direction and opposed to the third region of the first transistor section via a gate insulating film.

6. The device according to claim 5, wherein the first transistor section is a MOS transistor having a surround gate structure.

7. The device according to claim 3, wherein
the first contact plug includes a wiring section provided between the first transistor section and the bit line, and
the wiring section includes an interlayer wiring in contact with the first transistor section.

8. The device according to claim 7, wherein cross-sectional area of the interlayer wiring in a plane including the first direction and the second direction is larger than cross-sectional area of the transistor section.

9. The device according to claim 7, wherein the interlayer wiring is a metal wiring including tungsten (W).

10. The device according to claim 5, wherein the first select gate is provided on an interlayer insulating film covering the memory cell string.

11. The device according to claim 10, wherein the first contact plug includes a wiring section provided between the memory cell string and the first transistor section.

12. The device according to claim 10, wherein the bit line is in contact with the transistor section.

13. The device according to claim 1, wherein
the first contact plug includes:
the first transistor section in contact with the bit line; and
a wiring section provided between the memory cell string and the first transistor section,
wherein the first transistor section includes:
a second region of a first conductivity type connected to the bit line;
a third region of a second conductivity type provided between the second region and the wiring section; and
a first select gate provided on an interlayer insulating film covering the memory cell string, the first select gate being opposed to the third region via a gate insulating film.

14. The device according to claim 5, further comprising:
a second contact plug connected to the bit line and the other of the two adjacent memory cell strings and including a second transistor section controlling a current flowing in the other of the adjacent memory cell strings,
wherein the second transistor section controls the current flowing in the other memory cell string by a second select gate different from the first select gate of the first transistor section.

15. The device according to claim 14, further comprising:
an interlayer wiring being in contact with both the first transistor section and the second transistor section.
